(19) United States
(12) Patent Application Publication
(10) Pub. No.: US 2026/0231500 A1
(43) Pub. Date: Aug. 6, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Kosuke MIURA, Kawasaki Kanagawa (JP); Takeshi SUWA, Kawasaki Kanagawa (JP); Ryohei NEGA, Yokohama Kanagawa (JP)

(21) Appl. No.: 19/369,125

(22) Filed: Oct. 24, 2025

(30) Foreign Application Priority Data
Jan. 6, 2025 (JP) 2025-001894

(51) Int. Cl. H10D 64/00; H10D 30/47; H10D 62/85

(52) U.S. Cl. CPC H10D 64/118; H10D 30/475; H10D 62/8503

(57) ABSTRACT

According to an embodiment, a semiconductor device includes a first semiconductor layer, a second semiconductor layer, a third semiconductor layer, a fourth semiconductor layer, an insulating layer, a first electrode, a second electrode, and a third electrode. The third semiconductor layer is provided on the second semiconductor layer and includes Alₓ₃Ga₁₋ₓ₃N (0 ≤ x3 ≤ 1). The fourth semiconductor layer is provided on the third semiconductor layer and includes Alₓ₄Ga₁₋ₓ₄N (0 ≤ x4 < 1, x3 ≠ x4). The third semiconductor layer and the fourth semiconductor layer are provided between the second electrode and the third electrode.

### CROSS-REFERENCE TO RELATED APPLICATIONS

This application is based upon and claims the benefit of priority from Japanese Patent Application No. 2025-001894, filed on January 6, 2025; the entire contents of which are incorporated herein by reference.

### FIELD

Embodiments of the invention relate to a semiconductor device.

### BACKGROUND

For example, improvement in characteristics is desired for a semiconductor device, such as a transistor, in which a nitride semiconductor is used.

### BRIEF DESCRIPTION OF THE DRAWINGS

FIG. 1 is a schematic cross-sectional view of a semiconductor device according to a first embodiment;

FIG. 2 is a diagram illustrating characteristics of the semiconductor device according to the first embodiment;

FIG. 3 is a schematic cross-sectional view of a semiconductor device according to a second embodiment;

FIG. 4 is a schematic cross-sectional view of a semiconductor device according to a third embodiment;

FIG. 5 is a schematic cross-sectional view of a semiconductor device according to a fourth embodiment;

FIG. 6 is a schematic cross-sectional view of a semiconductor device according to the fifth embodiment;

FIG. 7 is a schematic cross-sectional view of a semiconductor device according to a sixth embodiment; and

FIG. 8 is a schematic cross-sectional view of a semiconductor device according to the seventh embodiment.

### DETAILED DESCRIPTION

According to an embodiment of the invention, a semiconductor device includes a first semiconductor layer, a second semiconductor layer, a third semiconductor layer, a fourth semiconductor layer, an insulating layer, a first electrode, a second electrode, and a third electrode. The first semiconductor layer includes Alₓ₁Ga₁₋ₓ₁N (0 ≤ x1 < 1). The second semiconductor layer is provided on the first semiconductor layer and includes Alₓ₂Ga₁₋ₓ₂N (0 < x2 < 1). The third semiconductor layer is provided on a part of the second semiconductor layer and includes Alₓ₃Ga₁₋ₓ₃N (0 ≤ x3 ≤ 1). The fourth semiconductor layer is provided on the third semiconductor layer and includes Alₓ₄Ga₁₋ₓ₄N (0 ≤ x4 < 1, x3 ≠ x4). The insulating layer is provided on the second semiconductor layer. The first electrode and the second electrode are provided on the second semiconductor layer. The first electrode and the second electrode are electrically connected to the second semiconductor layer. The third electrode is provided on the insulating layer. The third electrode is provided between the first electrode and the second electrode in a first direction from the first electrode to the second electrode. The third semiconductor layer and the fourth semiconductor layer are provided between the second electrode and the third electrode in the first direction.

Hereinafter, embodiments of the invention will be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

In the specification and drawings, components similar to those described in regard to a drawing thereinabove are marked with like reference numerals, and a detailed description is omitted as appropriate.

### First Embodiment

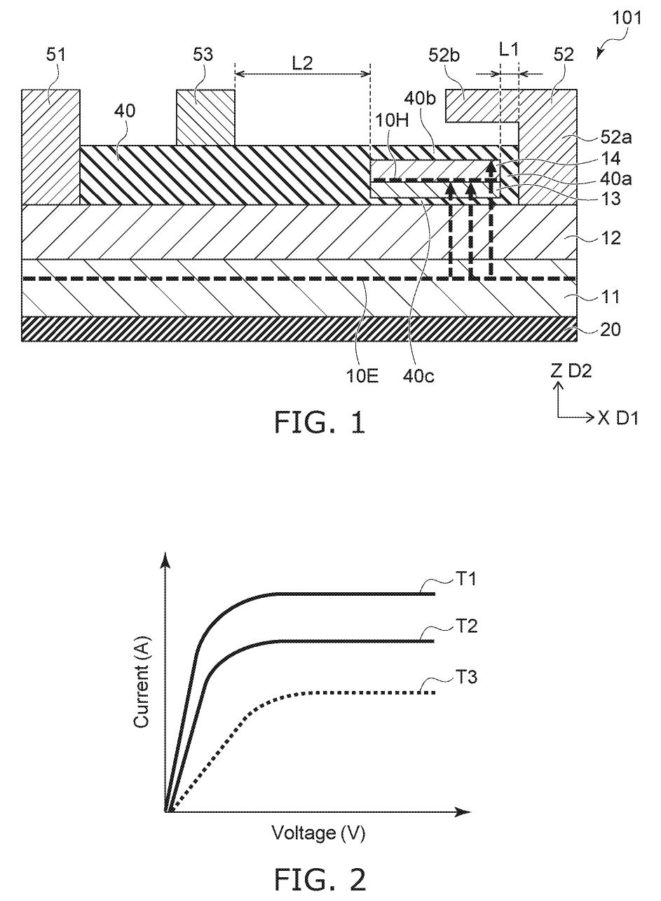

FIG. 1 is a schematic cross-sectional view of a semiconductor device according to a first embodiment.

As shown in FIG. 1, a semiconductor device 101 according to the first embodiment includes a first semiconductor layer 11, a second semiconductor layer 12, a third semiconductor layer 13, a fourth semiconductor layer 14, an insulating layer 40, a first electrode 51, a second electrode 52, and a third electrode 53.

A first direction D1 from the first electrode 51 to the second electrode 52 is taken as an X-axis direction. One direction perpendicular to the X-axis direction is taken as a Z-axis direction. The Z-axis direction is, for example, a second direction D2.

The first semiconductor layer 11 includes Alₓ₁Ga₁₋ₓ₁N (0 ≤ x1 < 1).

The second semiconductor layer 12 is provided on the first semiconductor layer 11. The second semiconductor layer 12 includes Alₓ₂Ga₁₋ₓ₂N (0 < x2 < 1).

The third semiconductor layer 13 is provided on a part of the second semiconductor layer 12. The third semiconductor layer 13 includes Alₓ₃Ga₁₋ₓ₃N (0 ≤ x3 ≤ 1).

The fourth semiconductor layer 14 is provided on the third semiconductor layer 13. The fourth semiconductor layer 14 includes Alₓ₄Ga₁₋ₓ₄N (0 ≤ x4 < 1, x3 ≠ x4).

The insulating layer 40 is provided on the second semiconductor layer 12.

The first electrode 51 and the second electrode 52 are provided on the second semiconductor layer 12. The first electrode 51 and the second electrode 52 are electrically connected to the second semiconductor layer 12.

The third electrode 53 is provided on the insulating layer 40. The third electrode 53 is provided between the first electrode 51 and the second electrode 52 in the first direction D1 from the first electrode 51 to the second electrode 52.

The third semiconductor layer 13 and the fourth semiconductor layer 14 are provided between the second electrode 52 and the third electrode 53 in the first direction D1.

The insulating layer 40 may function as a protective film that protects the third semiconductor layer 13 and the fourth semiconductor layer 14.

The current flowing between the first electrode 51 and the second electrode 52 can be controlled by a voltage applied to the third electrode 53. The first electrode 51 functions as, for example, a source electrode. The second electrode 52 functions as, for example, a drain electrode. The third electrode 53 functions as, for example, a gate electrode. The semiconductor device 101 is, for example, a transistor.

For example, the first semiconductor layer 11 includes a region facing the second semiconductor layer 12. In this region, a carrier region 10E is formed. The carrier region 10E is, for example, a two-dimensional electron gas. The semiconductor device 101 is, for example, a high electron mobility transistor (HEMT).

When a positive high voltage is applied to the second electrode 52, electrons move from the carrier region 10E toward the second electrode 52. A first reference example is conceivable in which the third semiconductor layer 13 and the fourth semiconductor layer 14 on the second semiconductor layer 12 are not provided between the second electrode 52 and the third electrode 53. In the first reference example, the electrons are accumulated in the insulating layer 40 near the second electrode 52. As a result, the polarization effect is weakened, and the carrier (electron) concentration in the carrier region 10E in the vicinity of the second electrode 52 decreases. For example, the on-resistance increases. For example, current collapse occurs.

In the semiconductor device 101 according to the embodiment, the third semiconductor layer 13 and the fourth semiconductor layer 14 are provided between the second electrode 52 and the third electrode 53. A hole gas 10H is generated at the interface between the third semiconductor layer 13 and the fourth semiconductor layer 14. The electrons entering from below the third semiconductor layer 13 and the hole gas 10H are combined, and are less likely to reach the insulating layer 40 on the fourth semiconductor layer 14. The electrons are less likely to be accumulated in the insulating layer 40 around the third semiconductor layer 13 and the fourth semiconductor layer 14. As a result, the polarization effect is prevented from being weakened. The movement of the electrons from the carrier region 10E in the vicinity of the second electrode 52 is suppressed. Accordingly, an increase in the on-resistance can be suppressed. For example, the occurrence of current collapse can be suppressed. According to the embodiment, the semiconductor device 101 whose characteristics can be improved can be provided.

FIG. 2 is a diagram illustrating characteristics of the semiconductor device according to the first embodiment.

The horizontal axis in FIG. 2 represents a voltage applied to the second electrode 52. The vertical axis represents the current. FIG. 2 illustrates a first characteristic T1, a second characteristic T2, and a third characteristic T3. The first characteristic T1 is a characteristic before the occurrence of current collapse. The second characteristic T2 and the third characteristic T3 correspond to characteristics after the occurrence of current collapse. The second characteristic T2 corresponds to a characteristic of the semiconductor device 101. The third characteristic T3 corresponds to the first reference example. The first characteristic T1 corresponds to the semiconductor device 101 and the first reference example.

As shown in FIG. 2, the current in the semiconductor device 101 according to the embodiment is larger than the current in the first reference example. The rate of characteristic degradation in the semiconductor device 101 according to the embodiment is lower than the rate of characteristic degradation in the first reference example. The characteristics of the semiconductor device 101 according to the embodiment can be improved.

The semiconductor device 101 according to the first embodiment may include a substrate layer 20 provided under the first semiconductor layer 11.

The composition ratio x3 may be higher than the composition ratio x4. The Al concentration of the third semiconductor layer 13 may be higher than the Al concentration of the fourth semiconductor layer 14. This effectively prevents the polarization effect from being weakened.

The composition ratio x3 may be higher than the composition ratio x2. The Al concentration of the third semiconductor layer 13 may be higher than the Al concentration of the second semiconductor layer 12.

In one example, the difference between the Al composition ratio of the third semiconductor layer 13 and the Al composition ratio of the fourth semiconductor layer 14 may be 0.2 or more. In one example, the thickness of the third semiconductor layer 13 in the second direction D2 may be 0.02 μm or more and 0.04 μm or less. The thickness of the fourth semiconductor layer 14 in the second direction D2 may be 0.02 μm or more and 0.04 μm or less.

As shown in FIG. 1, in the first direction D1, a first distance L1 between the third semiconductor layer 13 and the second electrode 52 may be smaller than a second distance L2 between the third semiconductor layer 13 and the third electrode 53.

The length of the third semiconductor layer 13 in the first direction D1 may be equal to the length of the fourth semiconductor layer 14 in the first direction D1.

The second electrode 52 includes a first conductive portion 52a and a second conductive portion 52b. The first conductive portion 52a is on the second semiconductor layer 12. The second conductive portion 52b extends in a direction from the first conductive portion 52a to the third electrode 53. At least a part of the second conductive portion 52b is above at least a part of the fourth semiconductor layer 14. Electrons are likely to be accumulated in the insulating layer 40 below the second conductive portion 52b. As in the example of FIG. 1, since at least a part of the second conductive portion 52b is above at least a part of the fourth semiconductor layer 14, the polarization effect can be prevented from being weakened. The movement of electrons from the carrier region 10E in the vicinity of the second electrode 52 can be suppressed. For example, an increase in the on-resistance can be suppressed. For example, the occurrence of current collapse can be suppressed.

The insulating layer 40 may include a first insulating portion 40a. The first insulating portion 40a is provided between the third and fourth semiconductor layers 13 and 14 and the second electrode 52. The third semiconductor layer 13 and the fourth semiconductor layer 14 are not electrically connected to the second electrode 52.

The insulating layer 40 includes the first insulating portion 40a, a second insulating portion 40b, and a third insulating portion 40c. The first insulating portion 40a is provided between the third semiconductor layer 13 and the second electrode 52 and between the fourth semiconductor layer 14 and the second electrode 52. The second insulating portion 40b is on the fourth semiconductor layer 14. The third insulating portion 40c is provided between a part of the second semiconductor layer 12 and the third semiconductor layer 13.

x3 may be 0.2 or more. The third semiconductor layer 13 may include AlN.

The composition ratio x4 may be less than 0.01.

### Second Embodiment

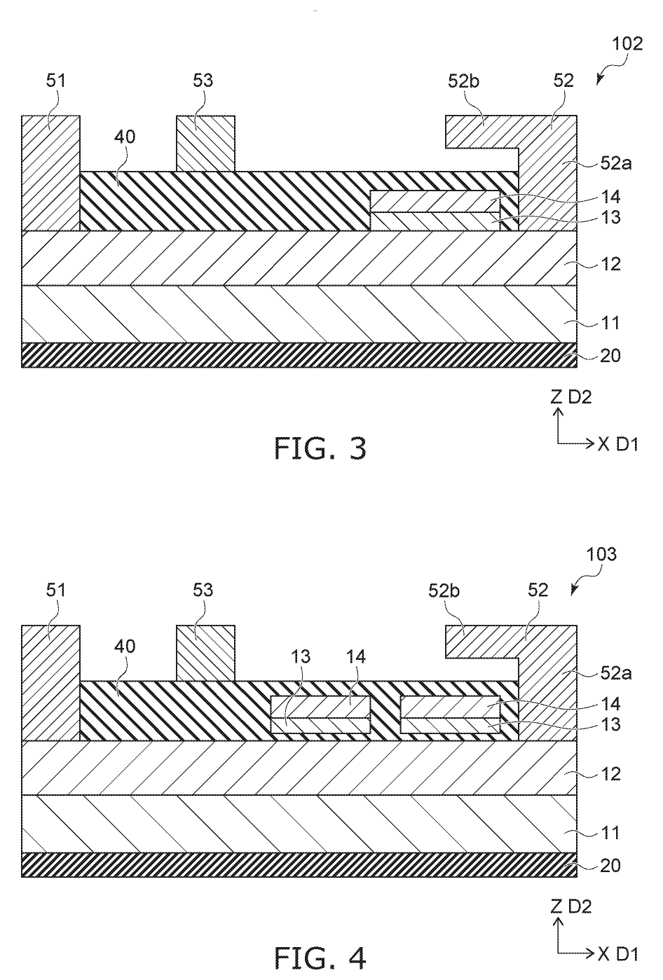

FIG. 3 is a schematic cross-sectional view of a semiconductor device according to a second embodiment.

In a semiconductor device 102 according to the second embodiment, the positions of the third semiconductor layer 13 and the fourth semiconductor layer 14 are different from the positions of the third semiconductor layer 13 and the fourth semiconductor layer 14 in the semiconductor device 101. The configuration of the semiconductor device 102 may be otherwise similar to the configuration of the semiconductor device 101.

As shown in FIG. 3, the third semiconductor layer 13 is in contact with a part of the second semiconductor layer 12.

### Third Embodiment

FIG. 4 is a schematic cross-sectional view of a semiconductor device according to a third embodiment.

The number of third semiconductor layers 13 and the number of fourth semiconductor layers 14 in a semiconductor device 103 according to the third embodiment are different from the number of third semiconductor layers 13 and the number of fourth semiconductor layers 14 in the semiconductor device 101 according to the first embodiment. The configuration of the semiconductor device 103 may be otherwise similar to the configuration of the semiconductor device 101.

As shown in FIG. 4, a plurality of third semiconductor layers 13 and a plurality of fourth semiconductor layers 14 are provided. The plurality of third semiconductor layers 13 are arranged along the first direction D1. The plurality of fourth semiconductor layers 14 are arranged along the first direction D1. The number of each of the third semiconductor layers 13 and the fourth semiconductor layers 14 is not limited.

### Fourth Embodiment

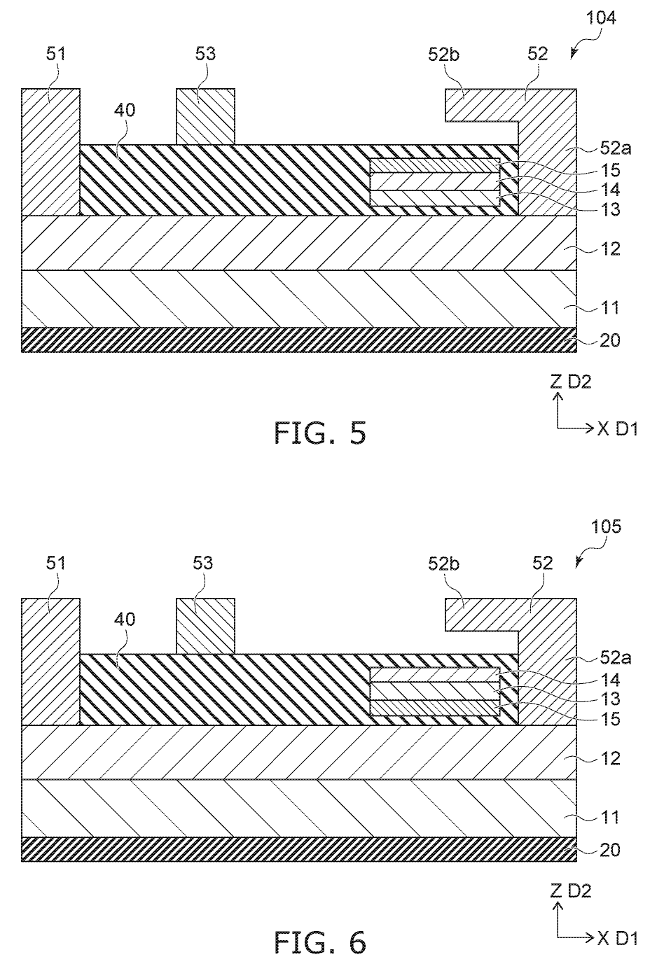

FIG. 5 is a schematic cross-sectional view of a semiconductor device according to a fourth embodiment.

In a semiconductor device 104 according to the fourth embodiment, another semiconductor layer is further provided in addition to the third semiconductor layer 13 and the fourth semiconductor layer 14. The configuration of the semiconductor device 104 may be otherwise similar to the configuration of the semiconductor device 101.

As shown in FIG. 5, the semiconductor device 104 further includes a fifth semiconductor layer 15 including Alₓ₅Ga₁₋ₓ₅N (0 ≤ x5 < 1). The fifth semiconductor layer 15 is provided on the fourth semiconductor layer 14. The composition ratio x5 may be lower than the composition ratio x3.

### Fifth Embodiment

FIG. 6 is a schematic cross-sectional view of a semiconductor device according to a fifth embodiment.

In a semiconductor device 105 according to the fifth embodiment, another semiconductor layer is further provided in addition to the third semiconductor layer 13 and the fourth semiconductor layer 14. The configuration of the semiconductor device 105 may be otherwise similar to the configuration of the semiconductor device 101.

As shown in FIG. 6, the semiconductor device 105 further includes the fifth semiconductor layer 15 including Alₓ₅Ga₁₋ₓ₅N (0 ≤ x5 < 1). The third semiconductor layer 13 may be provided between the fourth semiconductor layer 14 and the fifth semiconductor layer 15. The composition ratio x5 may be higher than the composition ratio x3.

### Sixth Embodiment

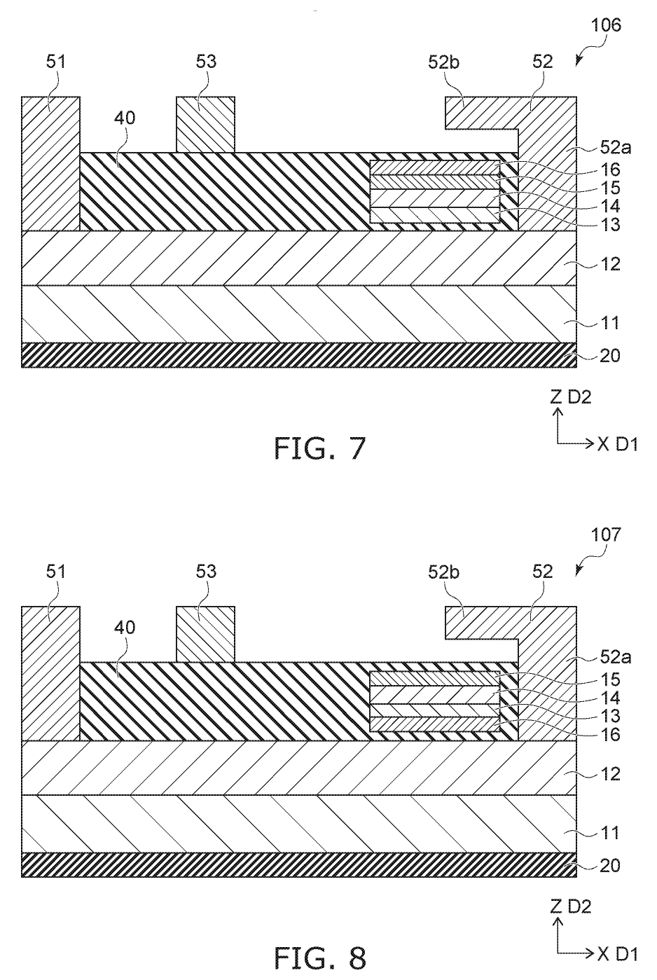

FIG. 7 is a schematic cross-sectional view of a semiconductor device according to a sixth embodiment.

In a semiconductor device 106 according to the sixth embodiment, another semiconductor layer is further provided in addition to the third semiconductor layer 13, the fourth semiconductor layer 14, and the fifth semiconductor layer 15. The configuration of the semiconductor device 106 may be otherwise similar to the configuration of the semiconductor device 104.

As shown in FIG. 7, the semiconductor device 106 according to the sixth embodiment further includes a sixth semiconductor layer 16 including Alₓ₆Ga₁₋ₓ₆N (0 ≤ x6 < 1). The sixth semiconductor layer 16 is provided on the fifth semiconductor layer 15.

### Seventh Embodiment

FIG. 8 is a schematic cross-sectional view of a semiconductor device according to a seventh embodiment.

In a semiconductor device 107 according to the seventh embodiment, another semiconductor layer is further provided in addition to the third semiconductor layer 13, the fourth semiconductor layer 14, and the fifth semiconductor layer 15. The configuration of the semiconductor device 107 may be otherwise similar to the configuration of the semiconductor device 105.

As shown in FIG. 8, the semiconductor device 107 according to the seventh embodiment further includes the sixth semiconductor layer 16 including Alₓ₆Ga₁₋ₓ₆N (0 ≤ x6 ≤ 1). The third semiconductor layer 13 may be provided between the fourth semiconductor layer 14 and the sixth semiconductor layer 16. The composition ratio x6 may be higher than each of the composition ratio x3, the composition ratio x4, and the composition ratio x5.

According to the embodiments, semiconductor devices whose characteristics can be improved can be provided.

In the specification, "perpendicular" and "parallel" not only refer to strictly perpendicular and strictly parallel but also allow, for example, variations caused during, for example, the manufacturing process, and need to be substantially perpendicular and substantially parallel.

Certain embodiments of the invention have been described above with reference to specific examples. However, the invention is not limited to these specific examples. For example, those skilled in the art may similarly practice the invention by selecting, as appropriate, specific configurations of components, such as semiconductor layers, electrodes, and the insulating layer 40, included in the semiconductor devices from known art. Such practice is included in the scope of the invention to the extent that similar effects are attained.

Any two or more components in the specific examples may be combined within the extent of technical feasibility and are included in the scope of the invention to the extent that the spirit of the invention is included.

Moreover, all semiconductor devices practicable by design modification made as appropriate by those skilled in the art based on the semiconductor devices described above as embodiments of the invention are also within the scope of the invention to the extent that the gist of the invention is included.

Moreover, various variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer including Alₓ₁Ga₁₋ₓ₁N (0 ≤ x1 < 1);
a second semiconductor layer provided on the first semiconductor layer and including Alₓ₂Ga₁₋ₓ₂N (0 < x2 < 1);
a third semiconductor layer provided on a part of the second semiconductor layer and including Alₓ₃Ga₁₋ₓ₃N (0 ≤ x3 ≤ 1);
a fourth semiconductor layer provided on the third semiconductor layer and including Alₓ₄Ga₁₋ₓ₄N (0 ≤ x4 < 1, x3 ≠ x4);
an insulating layer provided on the second semiconductor layer;
a first electrode and a second electrode provided on the second semiconductor layer and electrically connected to the second semiconductor layer; and
a third electrode provided on the insulating layer and provided between the first electrode and the second electrode in a first direction from the first electrode to the second electrode,
the third semiconductor layer and the fourth semiconductor layer being provided between the second electrode and the third electrode in the first direction.

2. The semiconductor device according to claim 1, wherein the x3 is higher than the x4.

3. The semiconductor device according to claim 1, wherein the x3 is higher than the x2.

4. The semiconductor device according to claim 1, wherein
a difference between an Al composition ratio of the third semiconductor layer and an Al composition ratio of the fourth semiconductor layer is 0.2 or more,
a thickness of the third semiconductor layer in a second direction crossing the first direction is 0.02 μm or more and 0.04 μm or less, and
a thickness of the fourth semiconductor layer in the second direction is 0.02 μm or more and 0.04 μm or less.

5. The semiconductor device according to claim 1, wherein
a plurality of the third semiconductor layers and a plurality of the fourth semiconductor layers are provided,
the plurality of third semiconductor layers are arranged along the first direction, and
the plurality of fourth semiconductor layers are arranged along the first direction.

6. The semiconductor device according to claim 1, wherein in the first direction, a first distance between the third semiconductor layer and the second electrode is smaller than a second distance between the third semiconductor layer and the third electrode.

7. The semiconductor device according to claim 1, wherein a length of the third semiconductor layer in the first direction is equal to a length of the fourth semiconductor layer in the first direction.

8. The semiconductor device according to claim 1, wherein
the second electrode includes a first conductive portion and a second conductive portion,
the first conductive portion is on the second semiconductor layer,
the second conductive portion extends in a direction from the first conductive portion to the third electrode, and
at least a part of the second conductive portion is above at least a part of the fourth semiconductor layer.

9. The semiconductor device according to claim 1, wherein
the insulating layer includes a first insulating portion,
the first insulating portion is provided between the third and fourth semiconductor layers and the second electrode, and
the third semiconductor layer and the fourth semiconductor layer are not electrically connected to the second electrode.

10. The semiconductor device according to claim 1, wherein
the insulating layer includes a first insulating portion, a second insulating portion, and a third insulating portion,
the first insulating portion is provided between the third semiconductor layer and the second electrode and between the fourth semiconductor layer and the second electrode,
the second insulating portion is on the fourth semiconductor layer, and
the third insulating portion is provided between a part of the second semiconductor layer and the third semiconductor layer.

11. The semiconductor device according to claim 1, wherein the third semiconductor layer is in contact with a part of the second semiconductor layer.

12. The semiconductor device according to claim 1, wherein the x3 is 0.2 or more.

13. The semiconductor device according to claim 1, wherein the x4 is less than 0.01.

14. The semiconductor device according to claim 1, further comprising:
a fifth semiconductor layer including Alₓ₅Ga₁₋ₓ₅N (0 ≤ x5 < 1),
the fifth semiconductor layer being provided on the fourth semiconductor layer.

15. The semiconductor device according to claim 14, wherein the x5 is lower than the x3.

16. The semiconductor device according to claim 1, further comprising:
a fifth semiconductor layer including Alₓ₅Ga₁₋ₓ₅N (0 ≤ x5 < 1),
the third semiconductor layer being provided between the fourth semiconductor layer and the fifth semiconductor layer.

17. The semiconductor device according to claim 16, wherein the x5 is higher than the x3.

18. The semiconductor device according to claim 14, further comprising:
a sixth semiconductor layer including Alₓ₆Ga₁₋ₓ₆N (0 ≤ x6 < 1),
the sixth semiconductor layer being provided on the fifth semiconductor layer.

19. The semiconductor device according to claim 14, further comprising:
a sixth semiconductor layer including Alₓ₆Ga₁₋ₓ₆N (0 ≤ x6 ≤ 1),
the third semiconductor layer being provided between the fourth semiconductor layer and the sixth semiconductor layer.

20. The semiconductor device according to claim 19, wherein the x6 is higher than each of the x3, the x4, and the x5.
